(19) United States
(12) Patent Application Publication
(10) Pub. No.: US 2009/0195989 A1
(43) Pub. Date: Aug. 6, 2009

(54) HEAT SINK COMPONENT AND A METHOD OF PRODUCING A HEAT SINK COMPONENT

(75) Inventor: Takuya ODA, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/363,815

(22) Filed: Feb. 2, 2009

(30) Foreign Application Priority Data
Feb. 4, 2008 (JP) 2008-023870
Jan. 14, 2009 (JP) 2009-005898

(51) Int. Cl. H05K 7/20; B21D 53/02

(52) U.S. Cl. 361/709; 29/890.03

(57) ABSTRACT

A heat sink component for a semiconductor package includes a thermal interface member including a thermally conductive material, and a heat sink member having a surface thereof that includes at least one projecting portion having a pointed shape or edge shape, a tip of which digs into the thermally conductive material.

### BACKGROUND OF THE INVENTION

1. Field of the Invention

The disclosures herein relate to a semiconductor package heat sink component including a thermally conductive material disposed on a semiconductor package.

2. Description of the Related Art

A semiconductor device such as a CPU (Central Processing Unit) is mounted in a fixed manner in a package while providing electrical connections. The temperature of such a semiconductor device becomes high during the device operation. Unless the temperature of the semiconductor device is reduced by an external means, the semiconductor device may suffer a performance drop, and may even break down. To this end, a heat sink plate or heat sink fin (or heat pipe) is mounted on the semiconductor device to provide a path through which the heat generated by the semiconductor device easily escapes to an exterior space. A thermal interface material (TIM) is placed between the semiconductor device and the heat sink plate or the like to closely follow their uneven surfaces for the purpose of reducing a thermal conductivity contact resistance thereby to achieve efficient thermal conduction.

FIG. 1 is a cross-sectional drawing showing an example of the arrangement of a related-art heat sink component placed on a semiconductor package. Heat generated by a semiconductor device 200 mounted on a substrate 100 propagates to a heat sink plate 400 through a thermal interface material 300 disposed on the semiconductor device 200. The heat conducted to the heat sink plate 400 then propagates to a heat sink fin 500 through a thermal interface material 300 disposed on the heat sink plate 400.

In this manner, the thermal interface material 300 serves as a means to thermally couple the semiconductor device 200 with the heat sink plate 400 and the heat sink plate 400 with the heat sink fin 500 without letting them have direct contact with each other.

The thermal interface material 300 is typically made of indium, which exhibits a satisfactory thermal conductivity. Indium is a rare metal, and is expensive. The stable supply of such a material in the future may not be guaranteed. Further, the configuration as described above requires a heat treatment such as reflow soldering for mounting the heat sink plate 400 in a fixed manner, which necessitates a complex manufacturing process.

In consideration of this, another material such as silicon grease or organic resin binder including a metal filler or graphite serving as highly thermal conductive material may be used as the thermal interface material 300. Alternatively, the thermal interface material 300 may be made of carbon nanotubes that are aligned in a heat conduction direction and shaped into a sheet by use of resin.

Documents that disclose related art devices and methods include Japanese Patent Application Publications No. 2005-347500, No. 2004-349497, and No. 2008-205273.

The thermal interface material 300 that is made of a thermally conductive material such as a metal filler or graphite shaped by use of resin may have a problem in its heat sink performance because the thermal conductivity of the resin is not sufficiently high. In the case of carbon nanotubes aligned in a thermal conduction direction, thermal conductivity contact resistance between the end face of carbon nanotubes and the heat sink component tends to be large, thereby failing to provide an expected level of performance.

FIG. 2 is a cross-sectional drawing showing a contact face between a related-art heat sink component and a thermal interface material inclusive of highly thermal conductive material. As shown in FIG. 2, a contact face between the heat sink plate 400 (or heat sink fin 500) and the thermal interface material 300 has a space 600 because their surfaces are rough as viewed microscopically. Further, the most external surfaces of the thermal interface material 300 are formed by low thermal conductive layers 301 in which the proportion of resin is high.

Because of the structure described above, there is no physical contact between the heat sink plate 400 and a highly thermal conductive material 302 such as a metal filler or graphite. This increases a thermal contact resistance between the heat sink plate 400 and the highly thermal conductive material 302 to reduce the thermal conduction. Thus, the structure does not provide sufficient heat sink properties.

Accordingly, there is a need to provide a semiconductor package heat sink component (i.e., a heat sink component for a semiconductor package) that has high thermal conductivity and satisfactory heat sink performance.

### SUMMARY OF THE INVENTION

It is a general object of the present invention to provide a heat sink component and a method of producing a heat sink component that substantially eliminate one or more problems caused by the limitations and disadvantages of the related art.

According to an embodiment, a heat sink component for a semiconductor package includes: a thermal interface member including a thermally conductive material; and a heat sink member having a surface thereof that includes at least one projecting portion having a pointed shape or edge shape, a tip of which digs into the thermally conductive material.

According to another embodiment, a method of producing a heat sink component for a semiconductor package, which includes a heat sink member and a thermal interface member including a thermally conductive material, includes the steps of: forming at least one projecting portion having a pointed shape or edge shape by performing one of press molding and micro-etching on a surface of the heat sink member that comes in contact with the thermal interface member; and applying a pressure to cause a tip of the projecting portion to dig into the thermally conductive material.

According to another embodiment, a method of producing a heat sink component for a semiconductor package, which includes a heat sink member and a thermal interface member including a thermally conductive material, includes the steps of: forming a layer having pointed-shape projecting portions by performing plating on a surface of the heat sink member that comes in contact with the thermal interface member; and applying a pressure to cause a tip of the pointed-shape projecting portion to dig into the thermally conductive material.

According to at least one embodiment of the present invention, a semiconductor package heat sink component that has high thermal conductivity and satisfactory heat sink performance can be provided.

### BRIEF DESCRIPTION OF THE DRAWINGS

Other objects and further features of the present invention will be apparent from the following detailed description when read in conjunction with the accompanying drawings, in which:

FIG. 1 is a cross-sectional drawing showing an example of the arrangement of a related-art heat sink component placed on a semiconductor package;

FIG. 2 is a cross-sectional drawing showing a contact face between a related-art heat sink component and a thermal interface material inclusive of highly thermal conductive material;

FIG. 3 is a cross-sectional view of a heat sink plate and a heat sink fin attached to a semiconductor package according to a present embodiment;

FIG. 4 is a cross-sectional view of a TIM that includes a low-thermal-conductivity material layer and a high-thermal-conductivity material;

FIG. 5 is an expanded, cross-sectional view of a contact face between the TIM and the heat sink plate or heat sink fin;

FIG. 6 is an expanded, cross-sectional view of the surface of the heat sink plate or heat sink fin that comes in contact with the TIM;

FIGS. 7A and 7B are expanded, plan views of the surface of the heat sink plate or heat sink fin that comes in contact with the TIM;

FIG. 8 is a cross-sectional view showing a variation of the heat sink plate or heat sink fin illustrated in FIG. 6;

FIG. 9 is a perspective view showing a variation of the heat sink plate or heat sink fin illustrated in FIG. 6;

FIG. 10 is a flowchart showing a process of manufacturing a semiconductor package heat sink component;

FIGS. 11A through 11C are drawings showing semiconductor package heat sink component assembling steps;

FIG. 12 is a flowchart of semiconductor packaging steps;

FIG. 13 is a drawing showing a rough-surface layer that has projecting portions formed by plating;

FIG. 14 is an expanded, cross-sectional view of a contact face between the TIM and the heat sink plate or heat sink fin shown in FIG. 13;

FIG. 15 is an expanded, cross-sectional view of a contact face between the heat sink plate or heat sink fin shown in FIG. 13 and a TIM that contains particles of highly thermal conductive material;

FIG. 16 is an expanded, cross-sectional view of a contact face between the heat sink plate or heat sink fin shown in FIG. 13 and a TIM that contains a highly thermal conductive material having a line shape;

FIG. 17 is a drawing showing a TIM in which pillars made of metal or carbon are situated to penetrate through a resin sheet;

FIG. 18 is an expanded, cross-sectional view of a contact face between the TIM shown in FIG. 17 and the heat sink plate or heat sink fin shown in FIG. 6;

FIG. 19 is an expanded, cross-sectional view of a contact face between a conventional heat sink plate and a TIM made of carbon nanotubes that are aligned in a heat conduction direction and shaped into a sheet by use of resin; and

FIG. 20 is an expanded, cross-sectional view of a contact face between the TIM shown in FIG. 19 and the heat sink plate or heat sink fin shown in FIG. 13.

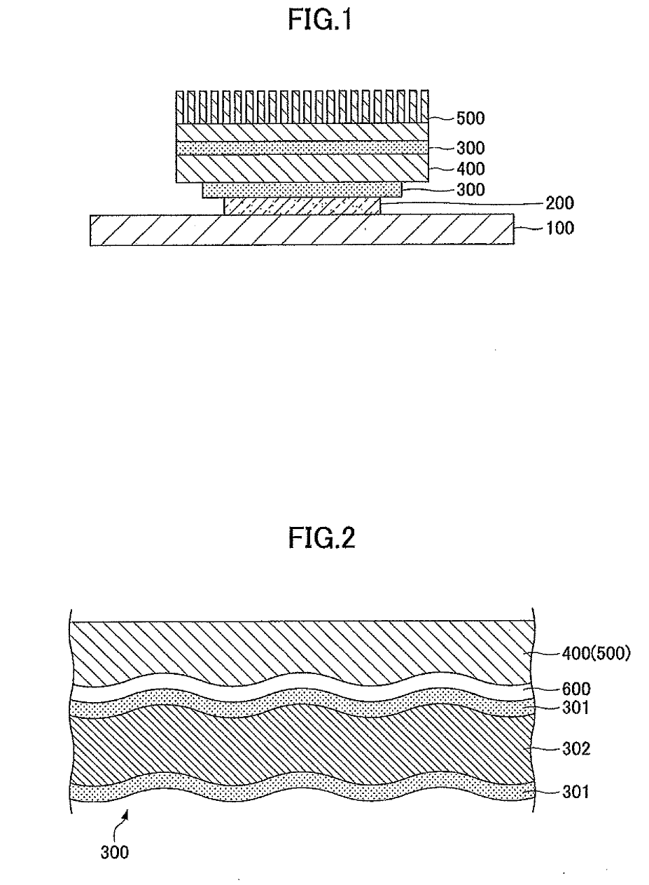

### DESCRIPTION OF THE PREFERRED EMBODIMENTS

In the following, embodiments for carrying out the present invention will be described by referring to the accompanying drawings.

[Semiconductor Package Heat Sink Component]

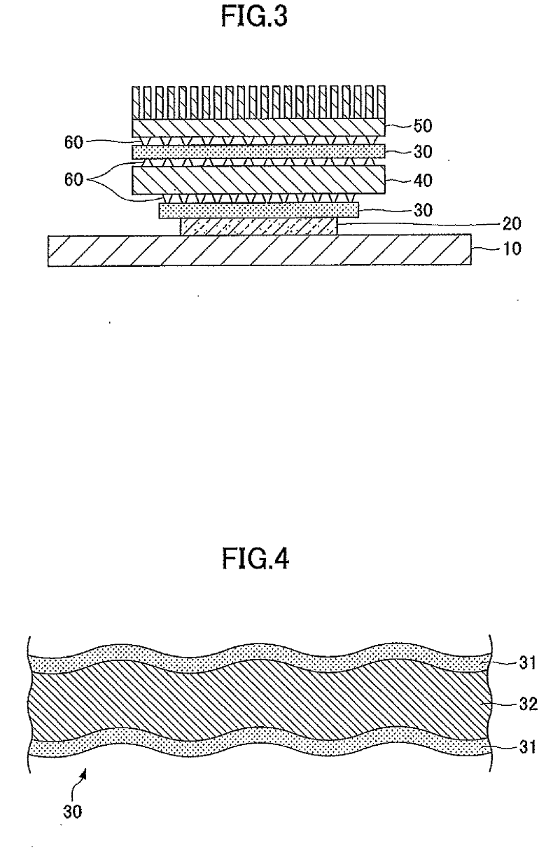

FIG. 3 is a cross-sectional view of a heat sink plate and a heat sink fin attached to a semiconductor package according to a present embodiment. As illustrated in FIG. 3, a heat sink plate 40 of the present embodiment is disposed on a TIM 30 serving as a thermal interface member placed on the upper surface of a semiconductor device 20 that is mounted on a substrate 10. A heat sink fin 50 of the present embodiment is disposed on a TIM 30 placed on the upper surface of the heat sink plate 40.

The TIM 30 includes a highly thermal conductive material such as metal filler, carbon filler, graphite, or carbon nanotubes, and is shaped by using an epoxy resin or organic resin as a major component. The TIM 30 may be made of carbon nanotubes that is aligned in a heat conduction direction and shaped into a sheet by use of resin.

The TIM 30 is placed between the semiconductor device 20 and the heat sink plate 40 to thermally couple the semiconductor device 20 with the heat sink plate 40. Also, the TIM 30 is placed between the heat sink plate 40 and the heat sink fin 50 to thermally couple the heat sink plate 40 with the heat sink fin 50.

The heat sink plate 40 may be a heat sink, and the heat sink fin 50 may be a heat sink fin provided with a heat pipe. The heat sink plate 40 and the heat sink fin 50 are made of a material having a good thermal conductivity such as aluminum or nickel-plated oxygen-free copper, and serve to conduct heat generated by the semiconductor device 20 to an exterior space. The thickness of the heat sink plate 40 may approximately be 0.5 to 2 mm.

As illustrated in FIG. 3, the surfaces of the heat sink plate 40 and the heat sink fin 50 that are in contact with the TIM 30 have projecting portions 60 that are formed by press molding. In the present embodiment, the projecting portions 60 are formed on the upper and lower surfaces of the heat sink plate 40. This is not a limiting example, and the projecting portions 60 may be formed only on one of the surfaces.

FIG. 4 is a cross-sectional view of the TIM that includes a low-thermal-conductivity material layer and a high-thermal-conductivity material. As illustrated in FIG. 4, the most external surfaces of the TIM 30 are low-thermal-conductivity material layers 31, and a high-thermal-conductivity material 32 is present inside the TIM 30 at a distance from these surfaces.

The low-thermal-conductivity material layer 31 contains a high proportion of resin and only a little proportion of high-thermal-conductivity material 32 such as a metal filler. The thermal conductivity of the low-thermal-conductivity material layer 31 is thus low.

The high-thermal-conductivity material 32 includes at least one of a metal filler made of conductive metal, a carbon filler, graphite, carbon nanotubes, and the like, which is provided with sufficient density to attain high thermal conductivity. The thickness of the TIM 30 is approximately 0.25 mm. The thickness of the low-thermal-conductivity material layer 31 is approximately 4 micrometers to 5 micrometers. The hardness of the low-thermal-conductivity material layer 31 is 40 to 90 Asker C, for example.

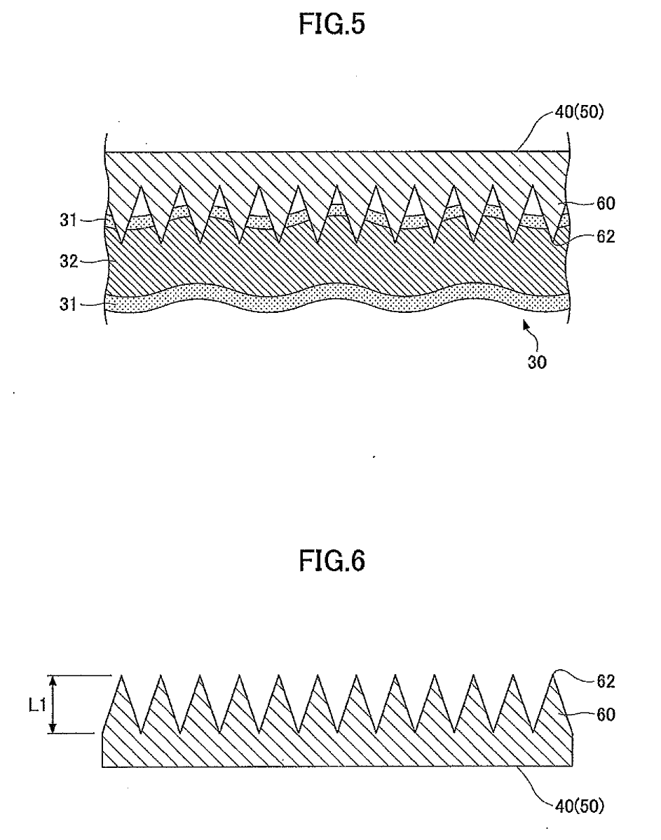

FIG. 5 is an expanded, cross-sectional view of a contact face between the TIM and the heat sink plate or heat sink fin. As shown in FIG. 5, the projecting portions 60 formed on the heat sink plate 40 or heat sink fin 50 have a needle shape (i.e., pointed shape) or blade shape (i.e., edge shape). Further, a tip 62 of each of the projecting portions 60 penetrates through the low-thermal-conductivity material layer 31 such as a resin binder formed in the surface of the TIM 30 to reach (i.e., dig into) the high-thermal-conductivity material 32 such as a metal filler.

Here, the term “needle shape” used as a description of the shape of the tip 62 of the projecting portions 60 refers to a sharp-pointed shape such as the shape of a needle. Here, the term “blade shape” refers to the tip 62 of the projecting portions 60 that forms a ridge (i.e., edge) rather than a point, as projecting portions 63 which will be described with reference to FIG. 9, wherein the angle of the faces forming the ridge is narrow to form a shape edge.

Further, the term “penetrate through” refers to the fact that the tips 62 of the projecting portions 60 pass through the low-thermal-conductivity material layer 31 of the TIM 30. The term “dig into” refers to the fact that the tips 62 of the projecting portions 60 cut into the high-thermal-conductivity material 32 of the TIM 30, including the fact that tips 62 reach and are in contact with the high-thermal-conductivity material 32.

FIG. 6 is an expanded, cross-sectional view of the surface of the heat sink plate or heat sink fin that comes in contact with the TIM. As shown in FIG. 6, the heat sink plate 40 or heat sink fin 50 has a plurality of projecting portions 60 having a triangular shape formed by press molding.

A height L1 from the bottom of the projecting portions 60 to the tip 62 is approximately 5 micrometers. The projecting portions 60 may be a triangular pyramid, a quadrangular pyramid, a circular cone, or the like. The projecting portions 60 have a Vickers hardness value of approximately 40 to 120 HV, for example.

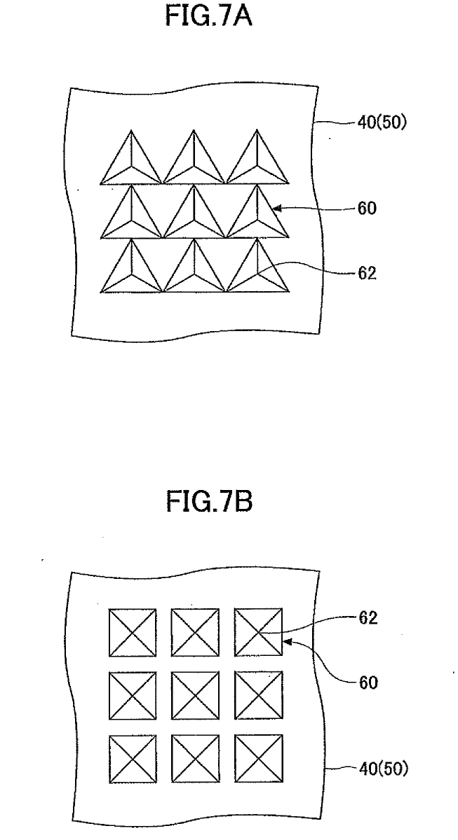

FIGS. 7A and 7B are expanded, plan views of the surface of the heat sink plate or heat sink fin that comes in contact with the TIM. As viewed from above, each of the projecting portions 60 of the heat sink plate 40 or heat sink fin 50 formed by press molding is a three-sided pyramid or four-sided pyramid (excluding the base).

FIG. 7A illustrates an example in which the projecting portions 60 are three-sided pyramids. As shown in FIG. 7A, the surface of the heat sink plate 40 that comes in contact with the TIM 30 has a plurality of three-sided-pyramid-shape projecting portions 60, which have the same shape and are arranged at constant intervals. FIG. 7B illustrates an example in which the projecting portions 60 are four-sided pyramids.

The arrangement of the projecting portions 60 on the surface of the heat sink plate 40 or heat sink fin 50 does not have to be a constant-interval arrangement. Any arrangement may suffice as long as the tips 62 of the projecting portions 60 dig into the high-thermal-conductivity material 32 to efficiently provide high-thermal-conduction performance.

[First Variation of Semiconductor Package Heat Sink Component]

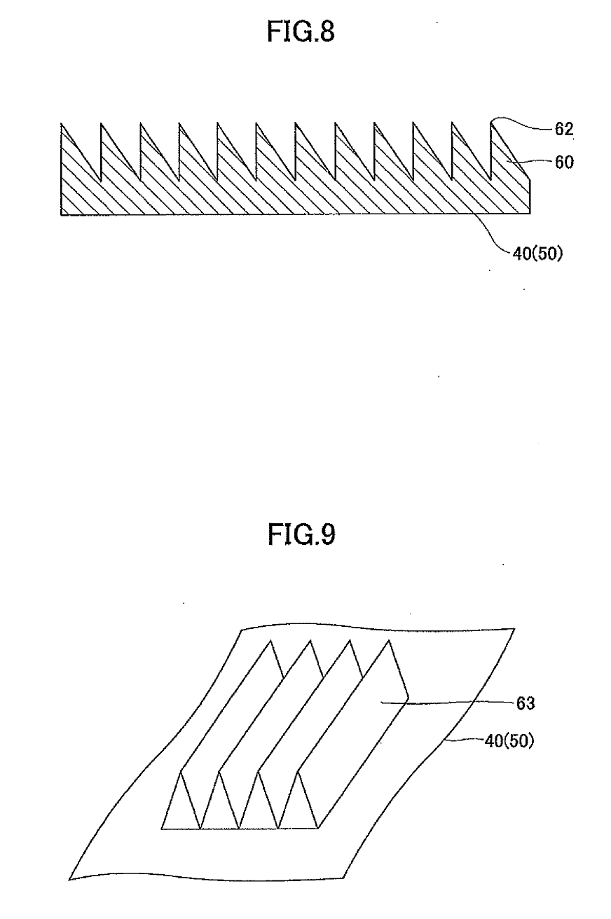

FIG. 8 is a cross-sectional view showing a variation of the heat sink plate or heat sink fin illustrated in FIG. 6. As shown in FIG. 8, the projecting portions 60 formed on the surface of the heat sink plate 40 or heat sink fin 50 that comes in contact with the TIM 30 are not limited to a triangular shape shown in FIG. 6, and may have a sawtooth shape as shown in FIG. 8 that is formed by press molding.

[Second Variation of Semiconductor Package Heat Sink Component]

FIG. 9 is a perspective view showing a variation of the heat sink plate or heat sink fin illustrated in FIG. 6. As shown in FIG. 9, the projecting portions 60 formed on the surface of the heat sink plate 40 or heat sink fin 50 that comes in contact with the TIM 30 may be projecting portions 63 each of which has an edge of a triangular prism as the “blade shape” tip formed by press molding.

The projecting portions 63 shown in FIG. 9 may be formed in parallel to each other on the surface of the heat sink plate 40 or heat sink fin 50 that comes in contact with the TIM 30, or may be formed partly in parallel and partly in perpendicular to each other. Their orientations may be any orientations.

In the present embodiment described above, the projecting portions 60 or 63 formed on the surface of the heat sink plate 40 or heat sink fin 50 that comes in contact with the TIM 30 have the sharp-pointed tips 62, which penetrate through the low-thermal-conductivity material layer 31 that contains a high proportion of resin binder used for the TIM 30. This arrangement increases the likelihood of the tips 62 of the projecting portions 60 reaching the high-thermal-conductivity material 32 such as a metal filler, graphite, carbon nanotubes that is present in the core portion of the TIM 30.

According to the present embodiment, further, the tips 62 of the projecting portions 60 are in physical contact with the high-thermal-conductivity material 32 that are present inside the TIM 30, thereby establishing a highly thermal conductive path. This reduces a thermal conductivity contact resistance between the TIM 30 and the heat sink plate 40 or heat sink fin 50. The resulting increase in thermal conductivity serves to provide a satisfactory heat sink property that allows the heat of the semiconductor device 20 shown in FIG. 3 to efficiently escape to an external space, where it may be transferred to an ambient medium by convection or radiation.

In the present embodiment, moreover, an increase in the surface area of the heat sink plate 40 or heat sink fin 50 brings about an increase in the contact area between the TIM 30 and the heat sink plate 40 or heat sink fin 50. This arrangement makes it possible to efficiently perform thermal conduction, thereby further improving heat sink performance.

[Method of Manufacturing a Semiconductor Package Heat Sink Component]

In the following, a method of manufacturing the heat sink plate 40 and the heat sink fin 50 will be described with the accompanying drawings.

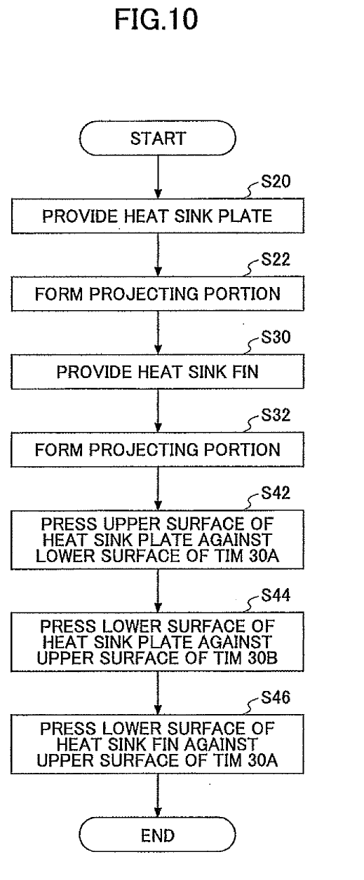

FIG. 10 is a flowchart showing a process of manufacturing a semiconductor package heat sink component. As shown in FIG. 10, the projecting portions 60 are formed on the heat sink plate 40 (S20 through S22). In step S20, the heat sink plate 40 made of nickel-plated oxygen-free copper, for example, is provided.

In step S22, the projecting portions 60 are formed by press molding on the one or more surfaces of the heat sink plate 40 that come in contact with the TIM 30. A conventional press molding is used for such press molding. In the present embodiment, the projecting portions 60 are formed on the upper and lower surfaces of the heat sink plate 40.

The projecting portions 60 may be needle-shaped or blade-shaped as shown in FIG. 3, FIG. 5, FIG. 6, FIG. 7A, FIG. 7B, FIG. 8, or FIG. 9. The projecting portions 60 are sufficiently sharp-pointed such that the tips 62 of the projecting portions 60 penetrate through the low-thermal-conductivity material layer 31 of the TIM 30 to dig into the high-thermal-conductivity material 32 when the heat sink plate 40 is pressed against the TIM 30, as will be described later.

More specifically, the angle of the two sides forming the tips 62 having a triangular shape or sawtooth shape shown in FIG. 6 or FIG. 8 is properly selected in response to the hardness of the projecting portions 60, the pressure applied by the heat sink plate 40 to the TIM 30, the thickness and hardness of the low-thermal-conductivity material layer 31, etc. In this manner, it is ensured that the tips 62 of the projecting portions 60 penetrate through the low-thermal-conductivity material layer 31 of the TIM 30 to dig into the high-thermal-conductivity material 32.

By the same token, the arrangement, positions, and number of the projecting portions 60 on the heat sink plate 40 are appropriately selected such that the tips 62 of the projecting portions 60 penetrate through the low-thermal-conductivity material layer 31 of the TIM 30 to dig into the high-thermal-conductivity material 32 when the heat sink plate 40 is pressed against the TIM 30 as will be described later.

In the manner described above, the projecting portions 60 are formed on the heat sink plate 40. In the heat sink component processing steps S20 through S22, a nickel (Ni) plate may be formed after the projecting portions 60 are formed on the oxygen-free-copper heat sink plate 40, for example.

Thereafter, the projecting portions 60 are similarly formed on the heat sink fin 50. The processes of forming the projecting portions 60 on the heat sink fin 50 will be described in the following (S30 through S32).

In step S30, the heat sink fin 50 made of aluminum having satisfactory thermal conductivity, for example, is provided. The heat sink fin 50 may be provided with a heat pipe. In step S32, the projecting portions 60 are formed by press molding on the surface of the heat sink fin 50 that comes in contact with the TIM 30. A conventional press molding is used for such press molding.

The shape of the projecting portions 60 and the arrangement, positions, and number of the projecting portions 60 formed on the projecting portions 60 are selected in the same manner as when the projecting portions 60 are formed on the heat sink plate 40 in step S22. In the manner described above, the projecting portions 60 are formed on the heat sink fin 50. These steps 330 through S32 may be performed simultaneously with or separately from the steps S20 through S22 that form the projecting portions 60 on the heat sink plate 40.

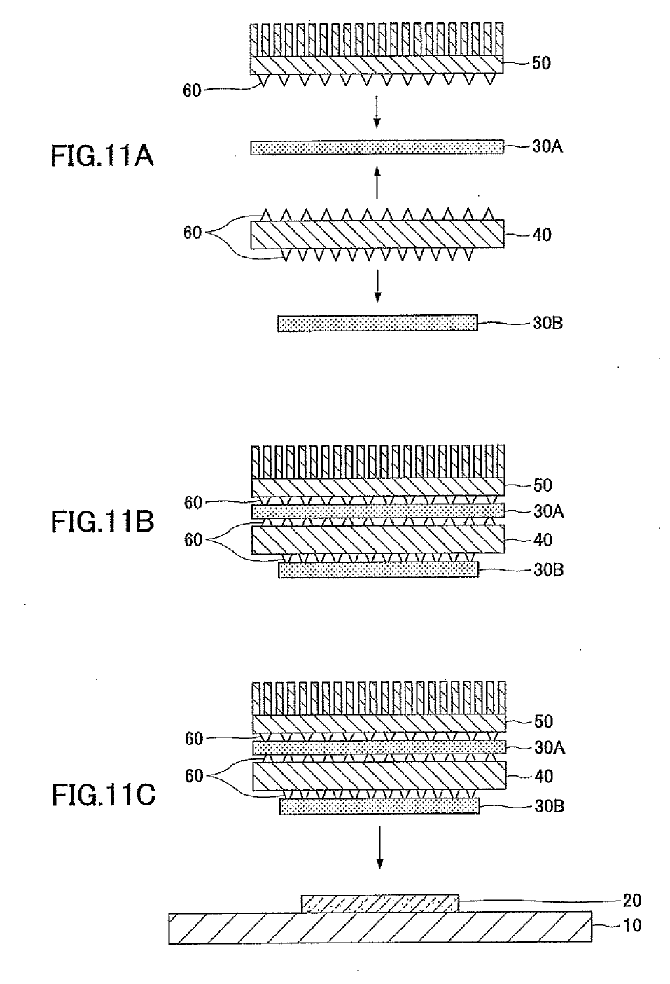

In the following, a process (S42 through S46) of attaching the heat sink plate 40 and the heat sink fin 50 having the projecting portions 60 formed thereon to the TIM 30 will be described by referring to FIGS. 11A through 11C. FIGS. 11A through 11C are drawings showing semiconductor package heat sink component assembling steps. Here, two TIMs 30 (i.e., TIM 30A and TIM 30B) are used.

In step S42, the TIM 30A and the heat sink plate 40 are provided, and the projecting portions 60 formed on the upper surface of the heat sink plate 40 are pressed against the lower surface of the TIM 30A as shown in FIG. 11A. In step S44, the projecting portions 60 formed on the lower surface of the heat sink plate 40 are pressed against the upper surface of the TIM 30B.

In step S46, the heat sink fin 50 is provided, and the projecting portions 60 formed on the lower surface of the heat sink fin 50 are pressed against the upper surface of the TIM 30A as shown in FIG. 11A.

In this manner, the heat sink plate 40 and the heat sink fin 50 are attached to the TIM 30A and 30B as shown in FIG. 11B.

The pressure applied in the steps S42 through S46 may be 0.5 MPa through 5 MPa. This pressure is selected such that the tips 62 of the projecting portions 60 penetrate through the low-thermal-conductivity material layer 31 to dig into the high-thermal-conductivity material 32. Specifically, this pressure is properly selected depending on the hardness (e.g., Vickers hardness 40 through 120 HV) of the surface of the heat sink plate 40, the sharpness of the tips 62, the density of the projecting portions 60, the thickness (e.g., approximately 4 to 5 micrometers) and hardness (e.g., 40 to 90 Asker C) of the low-thermal-conductivity material layer 31 of the TIM 30, etc.

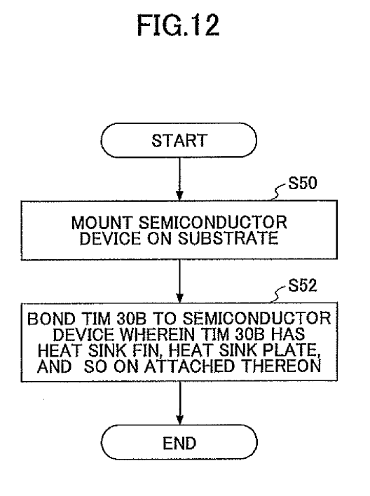

In what follows, semiconductor packaging steps will be described by referring to a view of the heat sink component shown in FIG. 11C. FIG. 12 is a flowchart of semiconductor packaging steps. As shown in FIG. 12, step S50 is a step of mounting the semiconductor device 20 on the substrate 10. In this step, the semiconductor device 20 is placed on the substrate 10, followed by fixing the semiconductor device 20 by use of a conventional method.

In step S52, the heat sink component produced by the heat sink component manufacturing steps that end with step S46 is attached in a fixed manner to the semiconductor device 20. To be specific, as shown in FIG. 11C, for example, the lower surface of the TIM 30B having the heat sink plate 40, the TIM 30A, and the heat sink fin 50 attached thereon is bonded in step S46 to the upper surface of the semiconductor device 20, which is mounted on the substrate 10 in step S50.

In this manner, the semiconductor package shown in FIG. 3 is completed. The sequence of the above-described steps may be altered as appropriate. For example, the lower surface of the TIM 30B having the heat sink plate 40 attached thereon may be bonded to the upper surface of the semiconductor device 20, followed by attaching the lower surface of the TIM 30A to the upper surface of the heat sink plate 40, and then attaching the heat sink fin 50 to the upper surface of the TIM 30A.

The heat sink plate 40 and the heat sink fin 50 assembled in the manner described above have the projecting portions 60 formed thereon that are in physical contact with the high-thermal-conductivity material 32. With this arrangement, a highly thermal conductive path is established by reducing a thermal conductivity contact resistance between the high-thermal-conductivity material 32 and the heat sink plate 40 or heat sink fin 50. That is, high thermal conductivity is provided. This improves a heat sink function that allows the heat of the semiconductor device 20 to efficiently escape to an external space, where it may be transferred to an ambient medium by convection or radiation.

The provision of the projecting portions 60 on the heat sink plate 40 or heat sink fin 50 increases the contact area of the heat sink plate 40 or heat sink fin 50 with the TIM 30. With this provision, the thermal conductivity between the TIM 30 and the heat sink plate 40 or heat sink fin 50 further increases, thereby further improving heat sink performance.

[First Variation of Method of Manufacturing a Semiconductor Package Heat Sink Component]

The projecting portions 60 of the heat sink plate 40 and the heat sink fin 50 formed by press molding in steps S22 and S32 may alternatively be formed by etching. Conventional etching may be used in such an etching step. An organic-acid-based micro-etching agent may be used.

[Second Variation of Method of Manufacturing a Semiconductor Package Heat Sink Component]

The projecting portions 60 of the heat sink plate 40 and the heat sink fin 50 formed by press molding in steps S22 and S32 may alternatively be formed by plating. FIG. 13 is a drawing showing a rough-surface layer that has projecting portions formed by plating.

As illustrated in FIG. 13, a rough-surface layer 70 formed by plating has needle-like projecting portions 72 whose tips 74 are sharp-pointed. The plating method for forming the rough-surface layer 70 may be either electroplating or nonelectrolytic plating.

The tips 74 of the projecting portions 72 are formed to be sharp, such that the tips 74 penetrate through the low-thermal-conductivity material layer 31 of the TIM 30 to dig into the high-thermal-conductivity material 32 when the heat sink plate 42 and the heat sink fin 50 are pressed against the TIMs 30A and 30B in the manufacturing steps S42 through S46.

Further, the pressure applied to the TIM 30 in steps S42 through S46 after forming the rough-surface layer 70 on the heat sink plate 40 and/or the heat sink fin 50 is selected such that the tips 74 of the projecting portions 72 penetrate through the low-thermal-conductivity material layer 31 to dig into the high-thermal-conductivity material 32. The pressure applied in steps S42 through S46 may be adjusted depending on the hardness of the projecting portions 72, the sharpness of the tips 74, the density of the projecting portions 72 on the heat sink plate 40 and/or the heat sink fin 50, the thickness and hardness of the low-thermal-conductivity material layer 31 of the TIM 30, etc.

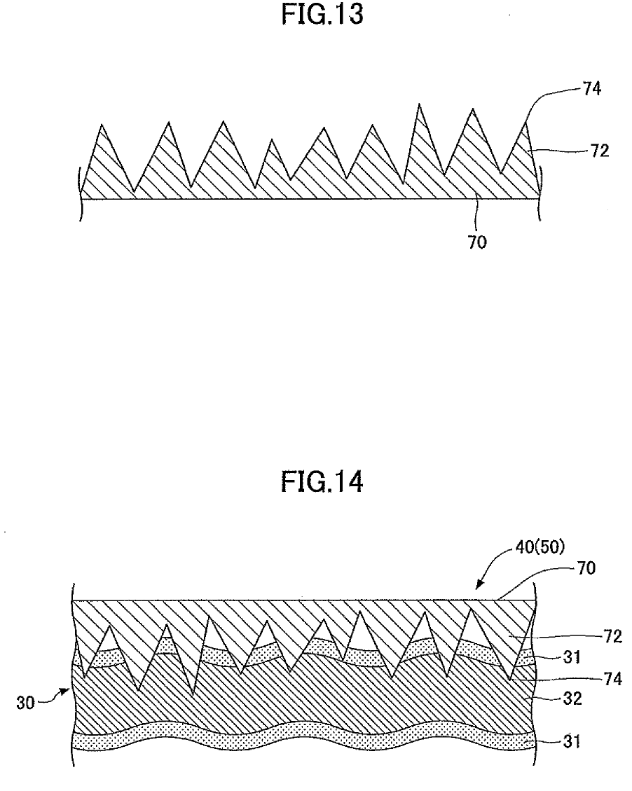

FIG. 14 is an expanded, cross-sectional view of a contact face between the TIM and the heat sink plate or heat sink fin shown in FIG. 13. As shown in FIG. 14, the tips 74 of the projecting portions 72 of the rough-surface layer 70 formed on the heat sink plate 40 or heat sink fin 50 by plating as described above penetrate through the low-thermal-conductivity material layer 31 of the TIM 30 to dig into the high-thermal-conductivity material 32.

Accordingly, the heat sink plate 40 and the heat sink fin 50 assembled in the manner described above have the projecting portions 72 formed thereon that are in physical contact with the high-thermal-conductivity material 32. With this arrangement, a highly thermal conductive path is established by reducing a thermal contact resistance between the high-thermal-conductivity material 32 and the heat sink plate 40 or heat sink fin 50. That is, high thermal conductivity is provided. This improves a heat sink function that allows the heat of the semiconductor device 20 to efficiently escape to an external space, where it may be transferred to an ambient medium by convection or radiation.

Further, the provision of the projecting portions 72 on the heat sink plate 40 or heat sink fin 50 increases the contact area of the heat sink plate 40 or heat sink fin 50 with the TIM 30. With this provision, the thermal conductivity between the TIM 30 and the heat sink plate 40 or heat sink fin 50 further increases, thereby further improving heat sink performance.

[Third Variation of Semiconductor Package Heat Sink Component]

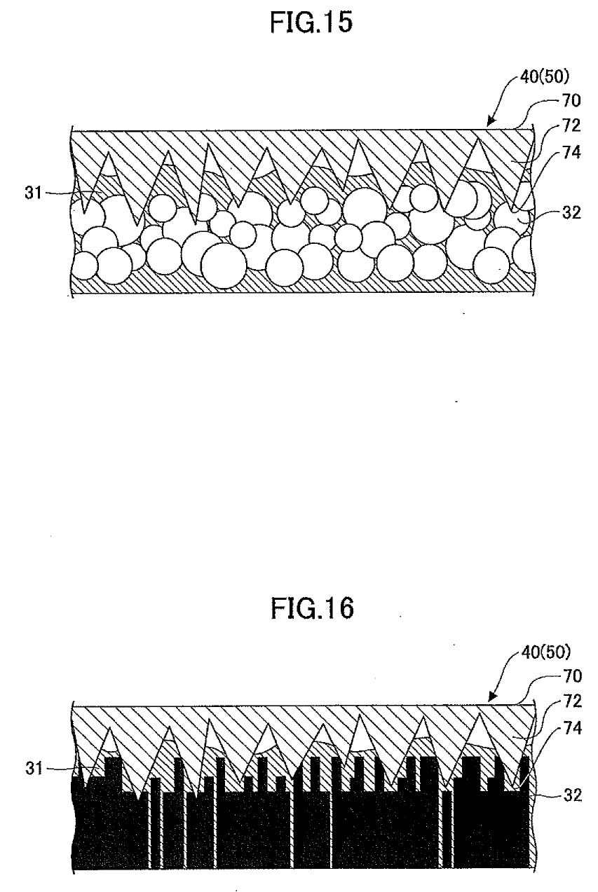

FIG. 15 is an expanded, cross-sectional view of a contact face between the heat sink plate or heat sink fin shown in FIG. 13 and a TIM that contains particles of highly thermal conductive material. The heat sink plate 40 or heat sink fin 50 illustrated in FIG. 15 has the rough-surface layer 70 formed thereon, which has the projecting portions 72. The tips 74 of the projecting portions 72 penetrate through the low-thermal-conductivity material layer 31 such as a resin binder existing in the surface of the TIM 30 to dig into the high-thermal-conductivity material 32 that is made of at least one of a metal filler, graphite, and the like.

[Fourth Variation of Semiconductor Package Heat Sink Component]

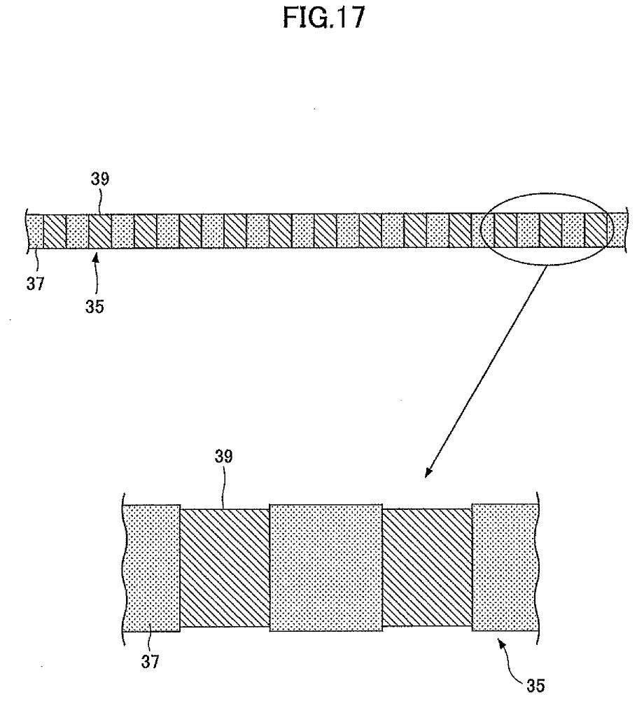

FIG. 16 is an expanded, cross-sectional view of a contact face between the heat sink plate or heat sink fin shown in FIG. 13 and a TIM that contains a highly thermal conductive material having a line shape. The heat sink plate 40 or heat sink fin 50 illustrated in FIG. 16 has the rough-surface layer 70 formed thereon, which has the projecting portions 72. Further, the tips 74 of the projecting portions 72 penetrate through the low-thermal-conductivity material layer 31 such as a resin binder existing in the surface of the TIM 30 to dig into the high-thermal-conductivity material 32 such as carbon nanotubes or the like having a line shape. The projecting portions 72 shown in FIG. 15 and FIG. 16 may alternatively be the projecting portions 60 shown in FIG. 6 or FIG. 8.

As shown in FIG. 15 and FIG. 16, the rough-surface layer 70 having the projecting portions 72 is formed on the heat sink plate 40 or heat sink fin 50, and the tips 74 of the projecting portions 72 penetrate through the low-thermal-conductivity material layer 31 that has a high proportion of resin binder. This arrangement increases the likelihood of the tips 74 of the projecting portions 72 reaching the high-thermal-conductivity material 32 such as a metal filler, graphite, carbon nanotubes existing in the core portion of the TIM 30. Further, the tips 74 of the projecting portions 72 are in physical contact with the high-thermal-conductivity material 32 that are present inside the TIM 30, thereby establishing a highly thermal conductive path. This reduces a thermal contact resistance between the TIM 30 and the heat sink plate 40 or heat sink fin 50.

Moreover, an increase in the surface area of the heat sink plate 40 or heat sink fin 50 brings about an increase in the contact area between the TIM 30 and the heat sink plate 40 or heat sink fin 50. This arrangement makes it possible to efficiently perform thermal conduction.

[Fifth Variation of Semiconductor Package Heat Sink Component]

FIG. 17 is a drawing showing a TIM in which pillars made of metal or carbon are situated to penetrate through a resin sheet. As illustrated in FIG. 17, a TIM 35 has a sheet shape in which a highly thermal conductive material 39 that are pillars made of metal, carbon, or the like penetrate through a resin sheet 37.

As illustrated in an expanded view, the surface of the resin sheet 37 and the surface of the highly thermal conductive material 39 are not flush with each other, such that the surface of the highly thermal conductive material metal pillars 39 forms a recess with respect to the resin surface of the resin sheet 37. Because of this, the use of a conventional heat sink plate results in an air layer being formed at the contact face between the heat sink plate and the TIM 35, thereby increasing a thermal conductivity contact resistance and lowering the thermal conductivity.

FIG. 18 is an expanded, cross-sectional view of a contact face between the TIM shown in FIG. 17 and the heat sink plate or heat sink fin shown in FIG. 6. As shown in FIG. 18, the surface of the heat sink plate 40 or heat sink fin 50 that comes in contact with the TIM 35 has the projecting portions 60. With this configuration, the sharp-pointed tips 62 of the projecting portions 60 of the heat sink plate 40 or heat sink fin 50 dig into the resin sheet 37 and highly thermal conductive material 39 of the TIM 35.

Accordingly, even when the surface of the highly thermal conductive material 39 is lower than the surface of the resin sheet 37, the tips 62 of the projecting portions 60 of the heat sink plate 40 or heat sink fin 50 have physical contact with the highly thermal conductive material 39 to establish a highly thermal conductive path. Moreover, the projecting portions 60 of the heat sink plate 40 or heat sink fin 50 bring about an increase in the contact area with the highly thermal conductive material 39, thereby making it possible to efficiently perform thermal conduction. This improves a heat sink function that allows the heat of the semiconductor device 20 to efficiently escape to an external space.

[Sixth Variation of Semiconductor Package Heat Sink Component]

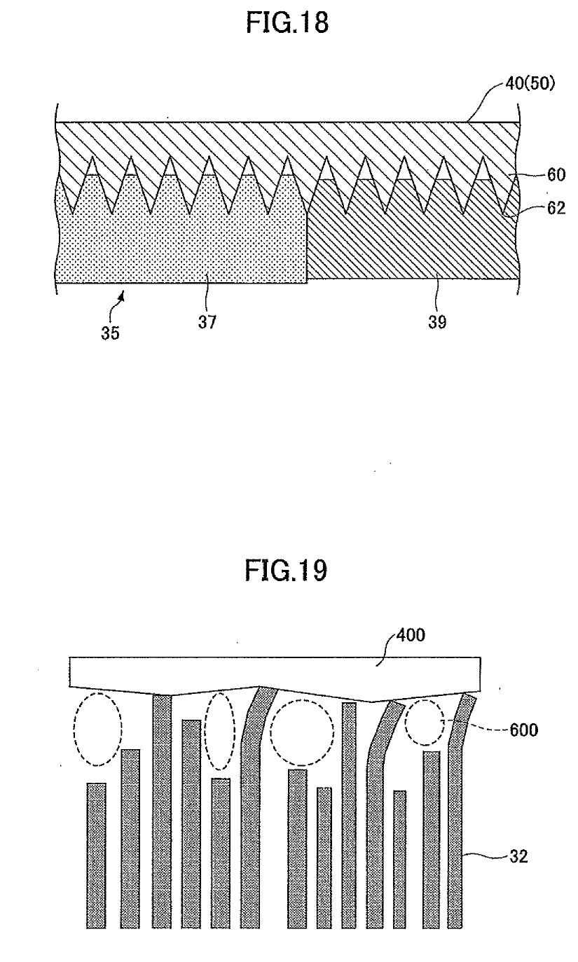

FIG. 19 is an expanded, cross-sectional view of a contact face between a conventional heat sink plate and a TIM made of carbon nanotubes that are aligned in a heat conduction direction and shaped into a sheet by use of resin. As shown in FIG. 19, the unevenness of the surface of the heat sink plate 400 is relatively small compared with the variation of lengths of line-shaped carbon nanotubes constituting the high-thermal-conductivity material 32. Because of this, short-length carbon nanotubes of the high-thermal-conductivity material 32 do not touch the surface of the heat sink plate 400, thereby creating spaces 600 between the surface of the heat sink plate 400 and the high-thermal-conductivity material 32.

Accordingly, a thermal contact resistance between the surface of the heat sink plate 400 and the high-thermal-conductivity material 32 increases to lower the thermal conductivity, thereby failing to provide satisfactory heat sink performance.

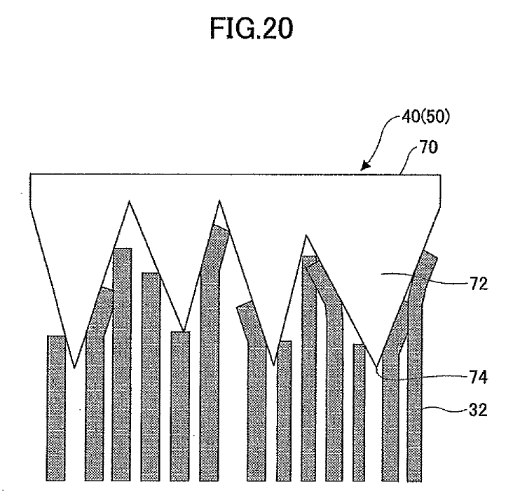

FIG. 20 is an expanded, cross-sectional view of a contact face between the TIM shown in FIG. 19 and the heat sink plate or heat sink fin shown in FIG. 13. As illustrated in FIG. 20, the rough-surface layer 70 having the projecting portions 72 is formed on an unevenness forming surface of the heat sink plate 40 or heat sink fin 50. The projecting portions 72 shown herein may alternatively be the projecting portions 60 shown in FIG. 6 or FIG. 8.

Further, the tips 74 of the projecting portions 72 dig into the high-thermal-conductivity material 32 such as a metal filler, carbon nanotubes, or the like that exists in the core or in the surface of the TIM 30.

This arrangement increases the likelihood of the tips 74 of the projecting portions 72 touching the high-thermal-conductivity material 32 such as a metal filler, carbon nanotubes, or the like existing in the core or in the surface of the TIM 30, thereby improving the thermal conductivity.

Moreover, an increase in the surface area of the heat sink plate 40 or heat sink fin 50 brings about an increase in the contact area between the TIM 30 and the heat sink plate 40 or heat sink fin 50. This arrangement makes it possible to efficiently perform thermal conduction.

According to at least one embodiment of the present invention described above, a semiconductor package heat sink component that has high thermal conductivity and satisfactory heat sink performance can be provided.

Further, the present invention is not limited to these embodiments, but various variations and modifications may be made without departing from the scope of the present invention.

The present application is based on Japanese priority applications No. 2008-023870 filed on Feb. 4, 2008 and No. 2009-5898 filed on Jan. 14, 2009, with the Japanese Patent Office, the entire contents of which are hereby incorporated by reference.

What is claimed is:

1. A heat sink component for a semiconductor package, comprising:
a thermal interface member including a thermally conductive material; and
a heat sink member having a surface thereof that includes at least one projecting portion having a pointed shape or edge shape, a tip of which digs into the thermally conductive material.

2. The heat sink component as claimed in claim 1, wherein the thermal interface member includes a first thermally conductive material region existing in a surface of the thermal interface member and a second thermally conductive material region existing at a depth from said surface, the first thermally conductive material region having a first thermal conductivity that is lower than a second thermal conductivity of the second thermally conductive material region, and wherein the tip of the projecting portion penetrates through the first thermally conductive material region to reach the second thermally conductive material region.

3. The heat sink component as claimed in claim 1, wherein the thermally conductive material includes at least one of a metal filler, a carbon filler, graphite, and a plurality of carbon nanotubes.

4. The heat sink component as claimed in claim 1, wherein the thermal interface member is made of a resin containing the thermally conductive material that includes at least one of a metal filler, a carbon filer, graphite, and carbon nanotubes.

5. A method of producing a heat sink component for a semiconductor package, which includes a heat sink member and a thermal interface member including a thermally conductive material, comprising the steps of:
forming at least one projecting portion having a pointed shape or edge shape by performing one of press molding and micro-etching on a surface of the heat sink member that comes in contact with the thermal interface member; and
applying a pressure to cause a tip of the projecting portion to dig into the thermally conductive material.

6. The method as claimed in claim 5, further comprising a step of forming the thermal interface member by use of a resin including the thermally conductive material.

7. A method of producing a heat sink component for a semiconductor packager which includes a heat sink member and a thermal interface member including a thermally conductive material, comprising the steps of:
forming a layer having pointed-shape projecting portions by performing plating on a surface of the heat sink member that comes in contact with the thermal interface member; and
applying a pressure to cause a tip of the pointed-shape projecting portion to dig into the thermally conductive material.

8. The method as claimed in claim 7, further comprising a step of forming the thermal interface member by use of a resin including the thermally conductive material.
